(19) United States
(12) Patent Application Publication
(10) Pub. No.: US 2022/0223383 A1
(43) Pub. Date: Jul. 14, 2022

(54) PROCESS SYSTEM WITH VARIABLE FLOW VALVE

(71) Applicant: Applied Materials, Inc., Santa Clara, CA (US)

(72) Inventors: Eric Kihara SHONO, San Mateo, CA (US); Vishwas Kumar PANDEY, Madhya Pradesh (IN); Hansel LO, San Jose, CA (US); Christopher S. OLSEN, Fremont, CA (US); Tobin KAUFMAN-OSBORN, Sunnyvale, CA (US); Tobin MAN-OSBORN, Santa Clara, CA (US); Rene GEORGE, San Carlos, CA (US); Lara HAWRYLCHAK, Gilroy, CA (US)

(21) Appl. No.: 17/600,243

(22) PCT Filed: Mar. 13, 2020
(86) PCT No.: PCT/US2020/022548

§ 371 Date: Sep. 30, 2021

(30) Foreign Application Priority Data
Apr. 5, 2019 (IN) 2019 41013831

(51) Int. Cl. H01J 37/32; C23C 16/455

(52) U.S. Cl. CPC H01J 37/32449; H01J 37/32357; C23C 16/4404; H01J 37/32477; C23C 16/45502

(57) ABSTRACT

Embodiments of the present disclosure generally relate to a process chamber for conformal oxidation of high aspect ratio structures. The process chamber includes a liner assembly that in one embodiment includes a body including a first opening and a second opening opposing the first opening, wherein the opening comprises a first end and a second end opposing the first end, and a flow valve disposed between the first opening and the second opening, the flow valve coupled to the body by a rotatable shaft that provides movement of the flow valve in angles between about 0 degrees and about 90 degrees relative to a central axis of the processing chamber.

### BACKGROUND

Embodiments of the present disclosure generally relate to process chambers for semiconductor device fabrication, and in particular to a process chamber having a valve providing variable plasma flow.

The production of silicon integrated circuits has placed difficult demands on fabrication operations to increase the number of devices while decreasing the minimum feature sizes on a chip. These demands have extended to fabrication operations including depositing layers of different materials onto difficult topologies and etching further features within those layers. Manufacturing processes for next generation NAND flash memory involve especially challenging device geometries and scales. NAND is a type of non-volatile storage technology that does not require power to retain data. To increase memory capacity within the same physical space, a three-dimensional NAND (3D NAND) design has been developed. Such a design typically introduces alternating oxide layers and nitride layers which are deposited on a substrate and then etched to produce a structure having one or more surfaces extending substantially perpendicular to the substrate. One structure may have over 100 such layers. Such designs can include high aspect ratio (HAR) structures with aspect ratios of 30:1 or more.

HAR structures are often coated with silicon nitride (SiNx) layers. Conformal oxidation of such structures to produce a uniformly thick oxide layer is challenging. New fabrication operations are needed to conformally deposit layers on HAR structures, rather than simply filling gaps and trenches.

Therefore, an improved process chamber and components for use therein are needed.

### SUMMARY

Embodiments of the present disclosure generally relate to semiconductor device fabrication, more particularly to a process chamber for conformal oxidation of high aspect ratio structures. The process chamber includes a liner assembly that in one embodiment includes a body including a first opening and a second opening opposing the first opening. The opening comprises a first end and a second end opposing the first end, and a flow valve is disposed between the first opening and the second opening. The flow valve is coupled to the body by a rotatable shaft that provides movement of the flow valve in angles between about 0 degrees and about 90 degrees relative to a central axis of the processing chamber.

In another embodiment, a processing system is disclosed which includes a process chamber coupled to a remote plasma chamber by a liner assembly. The liner assembly comprises a body including a first opening and a second opening opposing the first opening. The first opening comprises a first end and a second end opposing the first end. The body also includes a flow valve disposed between the first opening and the second opening, the flow valve coupled to the body by a rotatable shaft that provides movement of the flow valve in angles between about 0 degrees and about 90 degrees relative to a central axis of the process chamber.

In another embodiment, a process system includes a process chamber including a substrate support portion and a chamber body coupled to the substrate support portion. The chamber body includes a first side and a second side opposite the first side. The process chamber further includes a liner assembly disposed in the first side, wherein the liner assembly includes a flow valve that is rotatable relative to a centerline of the process chamber. The process chamber further includes a distributed pumping structure located in the substrate support portion adjacent to the second side, and a remote plasma source coupled to the process chamber by a connector, wherein the connector is connected to the liner assembly to form a fluid flow path from the remote plasma source to the processing volume.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1A is a cross-sectional view of a process system according to embodiments described herein.

FIG. 1B is a perspective view of the process system according to embodiments described herein.

FIG. 1C is a schematic top view of the process system according to embodiments described herein.

FIGS. 2A and 2B are schematic sectional top views of the process chamber.

FIG. 3 is a schematic isometric view of the liner assembly coupled to the connector.

FIG. 4 is a schematic isometric view of the liner assembly according to another embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to a process chamber for uniform film formation, for example conformal oxidation of high aspect ratio structures. The process chamber includes a liner assembly located in a first side of a chamber body and two pumping ports located in a substrate support portion adjacent a second side of the chamber body opposite the first side. A side pumping manifold is coupled to the process chamber. The side pumping manifold may be used alone or in combination with the two pumping ports to control the flow of radicals within the process chamber. The sde pumping manifold may be located either side of the process chamber. The liner assembly includes a flow valve to control the flow of radicals from the liner assembly to the pumping ports. The liner assembly may be fabricated from quartz to minimize interaction with process gases, such as radicals. The liner assembly is designed to reduce flow constriction of the radicals, leading to increased radical concentration and flux. The flow valve is provided in the liner assembly and may be used to tune the flow of the radicals through the processing region of the process chamber. Additionally, the two pumping ports can be individually controlled to tune the flow of the radicals through the processing region of the process chamber.

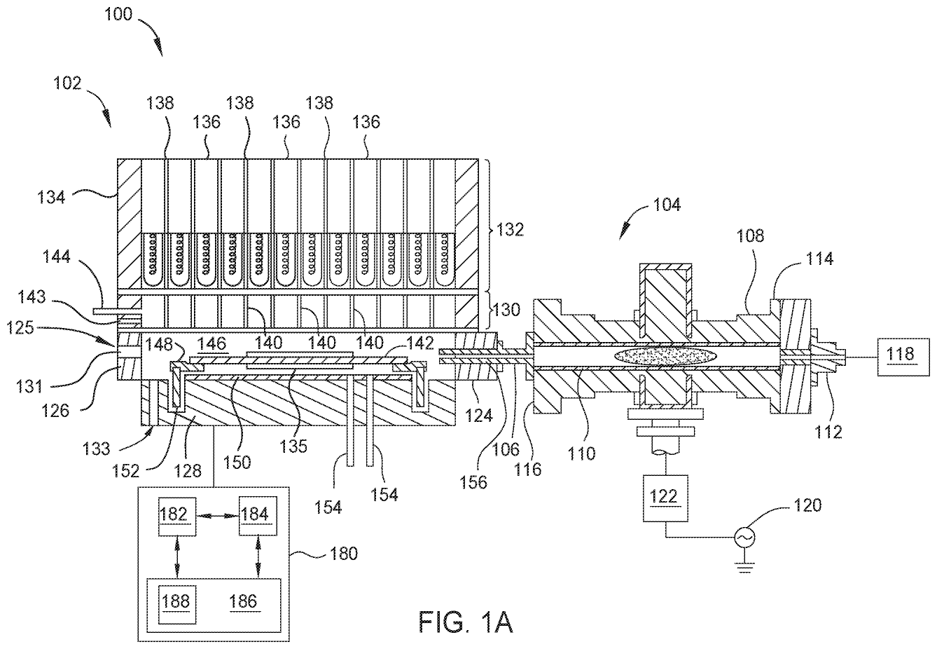

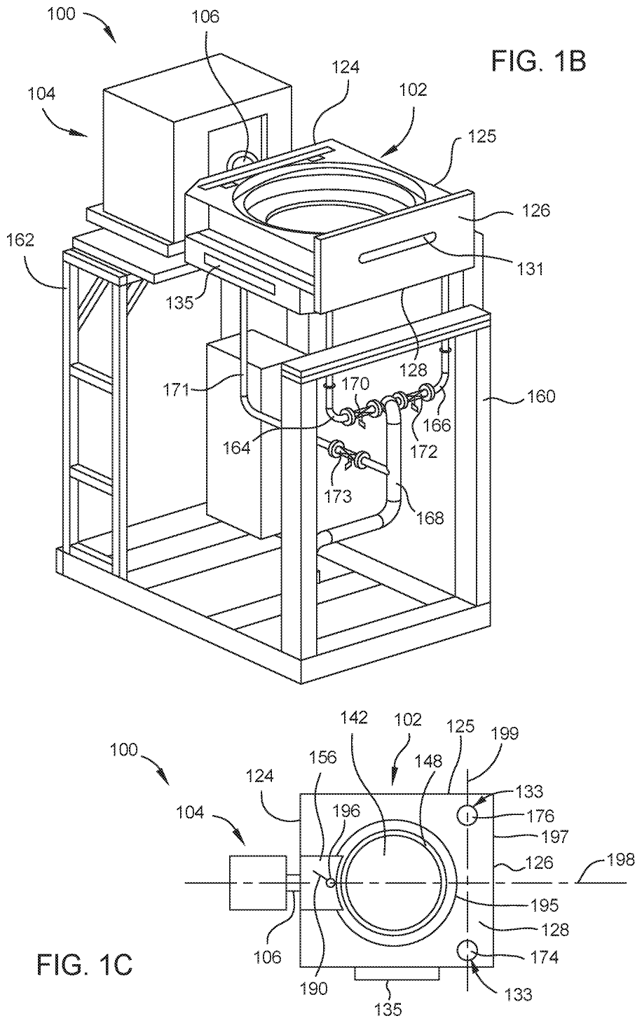

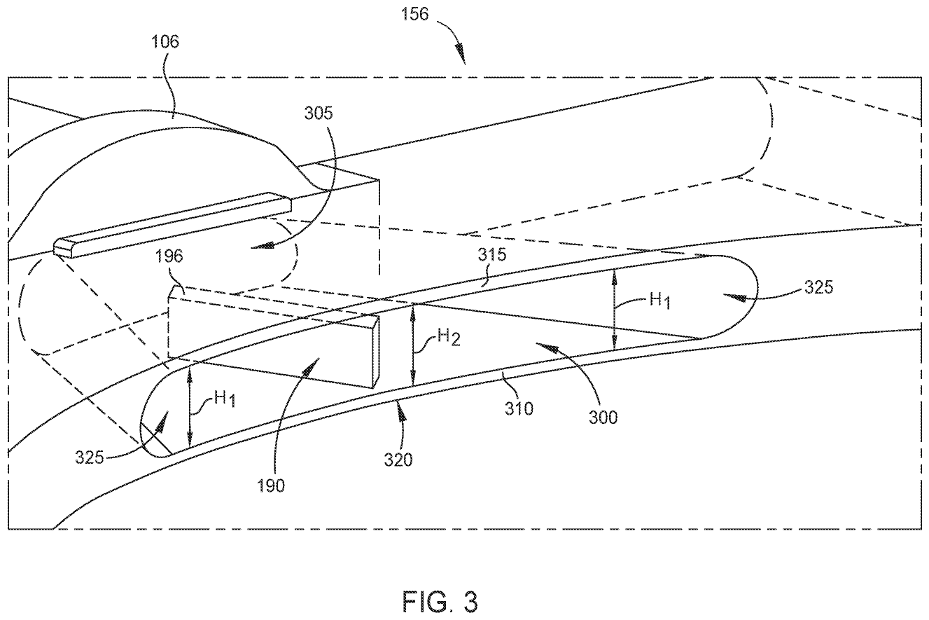

FIG. 1A is a cross-sectional view of a process system 100 according to embodiments described herein. The process system 100 includes a process chamber 102 and a remote plasma source 104. The process chamber 102 may be a rapid thermal processing (RTP) chamber. The remote plasma source 104 may be any suitable remote plasma source, such as a microwave coupled plasma source, that can operate at a power, for example, of about 6 kW. The remote plasma source 104 is coupled to the process chamber 102 to flow plasma formed in the remote plasma source 104 toward the process chamber 102. The remote plasma source 104 is coupled to the process chamber 102 via a connector 106. The components of the connector 106 are omitted in FIG. 1A for clarity, and the connector 106 is described in detail in connection with FIG. 3. Radicals formed in the remote plasma source 104 flow through the connector 106 into the process chamber 102 during processing of a substrate.

The remote plasma source 104 includes a body 108 surrounding a tube 110 in which plasma is generated. The tube 110 may be fabricated from quartz or sapphire. The body 108 includes a first end 114 coupled to an inlet 112, and one or more gas sources 118 may be coupled to the inlet 112 for introducing one or more gases into the remote plasma source 104. In one embodiment, the one or more gas sources 118 include an oxygen containing gas source, and the one or more gases include an oxygen containing gas. The body 108 includes a second end 116 opposite the first end 114, and the second end 116 is coupled to the connector 106. A coupling liner (not shown) may be disposed within the body 108 at the second end 116. The coupling liner is described in detail in connection with FIG. 3. A power source 120 (e.g., an RF power source) may be coupled to the remote plasma source 104 via a match network 122 to provide power to the remote plasma source 104 to facilitate the forming of the plasma. The radicals in the plasma are flowed to the process chamber 102 via the connector 106.

The process chamber 102 includes a chamber body 125, a substrate support portion 128, and a window assembly 130. The chamber body 125 includes a first side 124 and a second side 126 opposite the first side 124. A slit valve opening 131 is formed in the second side 126 of the chamber body 125 for allowing a substrate 142 to enter and exit the process chamber 102. In some embodiments, a lamp assembly 132 enclosed by an upper side wall 134 is positioned over and coupled to the window assembly 130. The lamp assembly 132 may include a plurality of lamps 136 and a plurality of tubes 138, and each lamp 136 may be disposed in a corresponding tube 138. The window assembly 130 may include a plurality of light pipes 140, and each light pipe 140 may be aligned with a corresponding tube 138 so the thermal energy produced by the plurality of lamps 136 can reach a substrate disposed in the process chamber 102. In some embodiments, a vacuum pressure is provided in the plurality of light pipes 140 by applying a vacuum to an exhaust 144 fluidly coupled to a volume formed within the plurality of light pipes 140. The window assembly 130 may have a conduit 143 formed therein for circulating a cooling fluid through the window assembly 130.

A processing region 146 may be defined by the chamber body 125, the substrate support portion 128, and the window assembly 130. The substrate 142 is disposed in the processing region 146 and is supported by a support ring 148 above a reflector plate 150. The support ring 148 may be mounted on a rotatable cylinder 152 to facilitate rotating of the substrate 142. The cylinder 152 may be levitated and rotated by a magnetic levitation system (not shown). The reflector plate 150 reflects energy to a backside of the substrate 142 to facilitate uniform heating of the substrate 142 and promote energy efficiency of the process system 100. A plurality of fiber optic probes 154 may be disposed through the substrate support portion 128 and the reflector plate 150 to facilitate monitoring a temperature of the substrate 142.

A liner assembly 156 is disposed in the first side 124 of the chamber body 125 for radicals to flow from the remote plasma source 104 to the processing region 146 of the process chamber 102. The liner assembly 156 may be fabricated from a material that is oxidation resistant, such as quartz, in order to reduce interaction with process gases, such as oxygen radicals. The liner assembly 156 is designed to reduce flow constriction of radical flowing to the process chamber 102. The liner assembly 156 is described in detail below. The process chamber 102 further includes a distributed pumping structure 133 formed in the substrate support portion 128 adjacent to the second side 126 of the chamber body 125 to control the flow of radicals from the liner assembly 156 to the pumping ports. The distributed pumping structure 133 is located adjacent to the second side 126 of the chamber body 125. The distributed pumping structure 133 is described in detail in connection with FIG. 1C.

The process chamber 102 further includes a side pumping manifold 135. The side pumping manifold 135 is formed in a sidewall of the chamber body 125 and is at least partially obscured by the substrate 142 in FIG. 1A. The side pumping manifold 135 is positioned on the chamber body 125 between the first side 124 and the second side 126. Like the distributed pumping structure 133, the side pumping manifold 135 is utilized to control the flow of radicals from the liner assembly 156 through the processing region 146. The side pumping manifold 135 may be used alone or in combination with the distributed pumping structure 133.

A controller 180 may be coupled to various components of the process system 100, such as the process chamber 102 and/or the remote plasma source 104 to control the operation thereof. The controller 180 generally includes a central processing unit (CPU) 182, a memory 186, and support circuits 184 for the CPU 182. The controller 180 may control the process system 100 directly, or via other computers or controllers (not shown) associated with particular support system components. The controller 180 may be one of any form of general-purpose computer processor that can be used in an industrial setting for controlling various chambers and sub-processors. The memory 186, or computer-readable medium, may be one or more of readily available memory such as random access memory (RAM), read only memory (ROM), floppy disk, hard disk, flash drive, or any other form of digital storage, local or remote. The support circuits 184 are coupled to the CPU 182 for supporting the processor in a conventional manner. The support circuits 184 include cache, power supplies, clock circuits, input/output circuitry and subsystems, and the like. Processing steps may be stored in the memory 186 as software routine 188 that may be executed or invoked to turn the controller 180 into a specific purpose controller to control the operations of the process system 100. The controller 180 may be configured to perform any methods described herein.

FIG. 1B is a perspective view of the process system 100 according to embodiments described herein. As shown in FIG. 1B, the process chamber 102 includes the chamber body 125 having the first side 124 and the second side 126 opposite the first side 124. The process system 100 is shown in FIG. 1B with the window assembly 130 and the lamp assembly 132 of FIG. 1A removed for clarity. The process chamber 102 may be supported by a frame 160 and the remote plasma source 104 may be supported by a frame 162. A first conduit 164 is coupled to one of the two pumping ports (not visible in FIG. 1B) and a valve 170 is provided in the first conduit 164 to control the flow of radicals within the process chamber 102. A second conduit 166 is coupled to the other pumping port (not visible in FIG. 1B) of the two pumping ports and a valve 172 is provided in the second conduit 166 to control the flow of radicals within the process chamber 102. A third conduit 171 is coupled to the side pumping manifold 135. A valve 173 is provided in the third conduit to control the flow of radicals within the process chamber 102. The first conduit 164, the second conduit 166, and the third conduit 171 are coupled to a main exhaust conduit 168, which may be connected to a vacuum pump (not shown).

FIG. 1C is a schematic top view of the process system 100 of FIG. 1A according to embodiments described herein. As shown in FIG. 1C, the process system 100 includes the remote plasma source 104 coupled to the process chamber 102 via the connector 106. The process system 100 is shown in FIG. 1C with the window assembly 130 and the lamp assembly 132 of FIG. 1A removed for clarity. The process chamber 102 includes the chamber body 125 having the first side 124 and the second side 126. The chamber body 125 may include an interior edge 195 and an exterior edge 197. The exterior edge 197 may include the first side 124 and the second side 126. The interior edge 195 may have a shape similar to the shape of a substrate being processed in the process chamber 102. In one embodiment, the interior edge 195 of the chamber body 125 is circular. The exterior edge 197 may be rectangular, as shown in FIG. 1C, polygonal, or other suitable shape. In one embodiment, the chamber body 125 is a base ring. The liner assembly 156 is disposed in the first side 124 of the chamber body 125. The liner assembly 156 includes a flow valve 190. The flow valve 190 is utilized to tune the flow of the radicals over the substrate 142. For example, the flow valve 190 may be used to deflect fluid flow from a center of the substrate 142, and/or provide a higher concentration of radicals near the edge of the substrate 142. Without the flow valve 190, an oxide layer formed on the substrate 142 may have a non-uniform thickness, such that the oxide layer at the center of the substrate is thicker than the oxide layer at the edge of the substrate. By utilizing the flow valve 190, the oxide layer formed on the substrate can have an enhanced thickness uniformity and conformality as compared to conventional approaches (e.g., without the flow valve 190).

The process chamber 102 includes a distributed pumping structure 133 having a two or more pumping ports 174 and 176. The two or more pumping ports are connected to one or more vacuum sources and independently flow controlled. In one embodiment, as shown in FIG. 1C, two pumping ports 174, 176 are formed in the substrate support portion 128 adjacent to the second side 126 of the chamber body 125. The two pumping ports 174, 176 are spaced apart and can be controlled independently or together based on process requirements. The pumping port 174 may be connected to the conduit 164 (FIG. 1B), and the pumping from the pumping port 174 can be controlled by the valve 170. The pumping port 176 may be connected to the conduit 166 (FIG. 1B), and the pumping from the pumping port 176 can be controlled by the valve 172. The oxide layer thickness uniformity can be further improved by individually and/or simultaneously controlling pumping from each pumping port 174, 176 to achieve desired thickness uniformity and conformality. Fluid, such as oxygen radicals, flowing through the process chamber 102 from the first side 124 to the second side 126 may be increased by opening valve 172 and/or valve 170 in a particular region within process chamber and change the uniformity and conformality of oxide thickness. Increased fluid flowing through the process chamber 102 can increase fluid density, such as oxygen radical density, leading to faster deposition on the substrate 142. Because the pumping port 174 and the pumping port 176 are spaced apart and controlled independently and/or simultaneously, fluid flowing across different portions of the substrate 142 can be increased or decreased, leading to faster or slower deposition on different portions of the substrate 142 to compensate for thickness non-uniformity of the oxide layer at different portions of the substrate 142. Additionally, the side pumping manifold 135 can be used alone or in combination with one or both of the pumping ports 174, 176 in order to further control radical flow.

In one embodiment, the two pumping ports 174, 176 are positioned in a spaced apart relation along a line 199. In one embodiment, the line 199 is perpendicular to a gas flow path from the first side 124 to the second side 126 of the chamber body 125. The line 199 may be adjacent to the second side 126 of the chamber body 125, and the line 199 may be outside of the substrate support ring 148, as shown in FIG. 1C. In some embodiments, the line 199 may intersect a portion of the substrate support ring 148. In some embodiments, the line 199 is not perpendicular to the gas flow path, and the line 199 may form an acute or obtuse angle with respect to the gas flow path. The pumping ports 174, 176 may be disposed symmetrically or asymmetrically in the substrate support portion 128 with respect to a central axis 198 of the process chamber 102, as shown in FIG. 1C. The side pumping manifold 135 is provided in an orientation that is orthogonal to the central axis 198 of the process chamber 102. The flow valve 190 is coupled to the liner assembly 156 at a pivot point 196. The pivot point comprises a rotatable shaft. In some embodiments, the pivot point 196 is positioned along the central axis 198 of the process chamber 102.

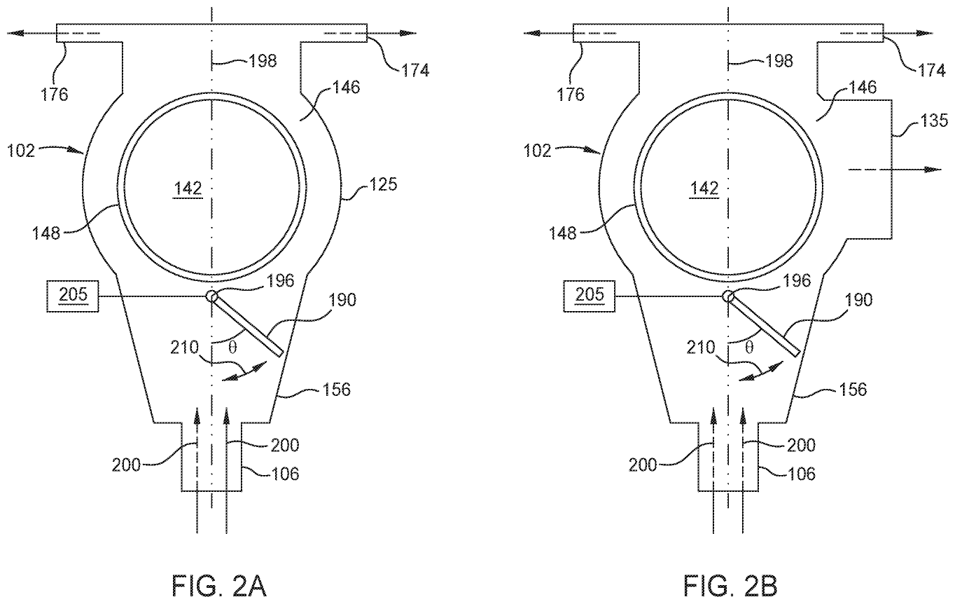

FIGS. 2A and 2B are schematic sectional top views of the process chamber 102. The window assembly 130 and the lamp assembly 132 shown in FIG. 1A are removed for clarity. In FIGS. 2A and 2B, a plasma flow path is indicated by arrows 200, which travels from the remote plasma source 104 (not shown) through the connector 106 to the processing region 146. In FIG. 2A, the pumping ports 174, 176 exhaust the plasma from the processing region 146. In FIG. 2B, the pumping ports 174, 176 as well as the side pumping manifold 135 are utilized to exhaust the plasma from the processing region 146. The flow path 200 is generally parallel to the central axis 198 of the process chamber 102 upstream of the flow valve 190. However, adjustment of the flow valve 190 changes the flow path 200 downstream of the flow valve 190.

The flow valve 190 is positioned within the plasma flow path 200. The flow valve 190 is positioned downstream of the remote plasma source 104 and the connector 106, and upstream of the substrate 142 positioned on the substrate support ring 148. The flow valve 190 is configured to rotate about the pivot point 196. The flow valve 190 may be rotated relative to the central axis 198 of the process chamber 102 to control the flow of radicals within the process chamber 102. The rotation is indicated by an angle θ. The angle θ may be varied along the direction indicated by the arrow 210. The angle θ may be varied between 0 degrees (parallel to the central axis 198 of the process chamber 102) up to about 90 degrees relative to the central axis 198 of the process chamber 102.

The flow valve 190 may be adjusted manually or be coupled to an actuator 205. In some embodiments, the angle θ of the flow valve 190 is adjusted between process runs after measurements are completed on a previously processed substrate. For example, oxide thickness uniformity of a first substrate is measured after processing in the process chamber 102. If the thickness uniformity of the first substrate is not up to specification, the flow valve 190 is then adjusted for processing a second substrate. Additionally, the oxide uniformity may be tuned by using different combinations of the pumping ports 174, 176 and the side pumping manifold 135.

FIG. 3 is a schematic isometric view of the liner assembly 156 coupled to the connector 106. A first opening 300 of the liner assembly 156 is shown. The first opening 300 is in fluid communication with the processing region 146 (FIG. 1A) of the process chamber 102 (not shown in FIG. 3). The first opening 300 opposes a second opening 305 that is coupled to the connector 106. The first opening 300 is larger than the second opening 305.

The first opening 300 includes a lower sidewall 310 and an upper sidewall 315. The lower sidewall 310 and the upper sidewall 315 may be planar across the first opening 300 or curved across the first opening 300. The first opening 300 includes a first height H₁ and a second height H₂. The first height H₁ may be the same as the second height H₂ , or the first height H₁ may be different than the second height H₂ . Varying one or both of the shape of the lower sidewall 310 and the upper sidewall 315, and the first height H₁ and the second height H₂ , may be provided to vary plasma flow through the liner assembly 156.

For example, the second height H₂ may be less than the first height H₁ such that one or both of the lower sidewall 310 and the upper sidewall 315 are curved inward (i.e., concave). In this example, a center area 320 of the first opening 300 is constricted as compared to ends 325 of the first opening 300.

Variations in the profile of the first opening 300 are utilized to maintain uniform flow on a wider area. In one implementation, variations in one or both of the shape of the lower sidewall 310 and the upper sidewall 315, and/or the first height Hi and the second height H₂ , provide a 35% reduction in the center area 320 of the first opening 300. In another implementation, variations in one or both of the shape of the lower sidewall 310 and the upper sidewall 315, and/or the first height H₁ and the second height H₂ , provide a 40% reduction in the center area 320 of the first opening 300. In another implementation, variations in one or both of the shape of the lower sidewall 310 and the upper sidewall 315, and/or the first height H₁ and the second height H₂ , provide a 60% reduction in the center area 320 of the first opening 300. In another implementation, variations in one or both of the shape of the lower sidewall 310 and the upper sidewall 315, and/or the first height H₁ and the second height H₂ , provide a 65% reduction in the center area 320 of the first opening 300.

Testing of the process chamber 102 having the liner assembly 156 and flow valve 190 as described herein was performed. The flow valve 190 was tested at varying angles (angle θ (shown in FIGS. 2A and 2B)) with the first opening 300 liner assembly 156 having various profiles. Center to edge uniformity of an oxide film was measured based on the tests.

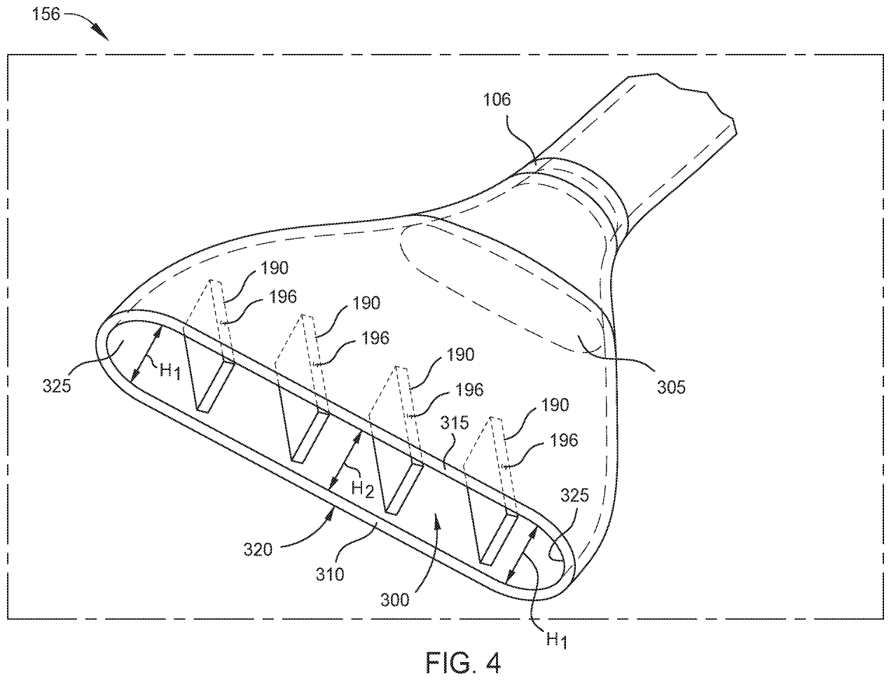

FIG. 4 is a schematic isometric view of the liner assembly 156 according to another embodiment. The liner assembly 156 coupled to the connector 106 as in other embodiments. The liner assembly 156 of FIG. 4 is similar to the liner assembly described in FIG. 3 with the exception of multiple flow valves 190. In addition, the pivot points 196 of the flow valves 190 is at or near a center of the respective flow valves 190. Other elements in FIG. 4 that are described in FIG. 3 will not be described again for brevity.

The multiple flow valves 190 are separated angularly and/or linearly with respect to each other as shown in FIG. 4. A length, a height and/or an angular position of each of the flow valves 190 may or may not be same. While four flow valves 190 are shown in FIG. 4, the number of flow valves may be more or less depending on process requirements.

The flow valve 190 as shown in FIG. 3 or the multiple flow valves 190 shown in FIG. 4 is/are utilized to direct plasma flow asymmetrically or offset with respect to the center of a substrate. Adjustment of the angle θ of the flow valve 190 is utilized such that no plasma is flowed directly to the center of the substrate. Due to the angular orientation of the flow valve 190, a certain amount of plasma flow is “dragged” by the substrate during rotation. The asymmetric plasma flow will provide a parallel and/or a straight constant thickness layer over a certain portion of the substrate as compared to conventional injection which is directed towards the center of the substrate. The layer thickness profile can be controlled or further modified using the various pumping schemes described above.

While the foregoing is directed to embodiments of the present disclosure, other and further embodiments of the disclosure may be devised without departing from the basic scope thereof, and the scope thereof is determined by the claims that follow.

What is claimed is:

1. A liner assembly for a semiconductor processing chamber, the liner assembly comprising:
a body including a first opening and a second opening opposing the first opening, wherein the opening comprises a first end and a second end opposing the first end; and
a flow valve disposed between the first opening and the second opening, the flow valve coupled to the body by a rotatable shaft that provides movement of the flow valve in angles between about 0 degrees and about 90 degrees relative to a central axis of the processing chamber.

2. The liner assembly of claim 1, wherein the body includes an upper sidewall and a lower sidewall bounding the first opening.

3. The liner assembly of claim 2, wherein one or both of the upper sidewall and the lower sidewall has a concave shape.

4. The liner assembly of claim 2, wherein the first opening has a center area between the first and second ends, and the first opening has about a 0% reduction to about a 80% reduction in the center area.

5. The liner assembly of claim 2, wherein the first opening has a center area between the first and second ends, and the first opening has a 40% reduction in the center area.

6. The liner assembly of claim 2, wherein the first opening has a center area between the first and second ends, and the first opening has a 60% reduction in the center area.

7. A processing system, comprising:
a process chamber coupled to a remote plasma chamber by a liner assembly, wherein the liner assembly comprises:
a body including a first opening and a second opening opposing the first opening, wherein the opening comprises a first end and a second end opposing the first end; and
a flow valve disposed between the first opening and the second opening, the flow valve coupled to the body by a rotatable shaft that provides movement of the flow valve in angles between about 0 degrees and about 90 degrees relative to the body.

8. The processing system of claim 7, wherein the body includes an upper sidewall and a lower sidewall bounding the first opening.

9. The processing system of claim 8, wherein one or both of the upper sidewall and the lower sidewall has a concave shape.

10. The processing system of claim 7, wherein the first opening has a center area between the first and second ends, and the first opening has about a 0% reduction to about a 80% reduction in the center area.

11. The processing system of claim 7, wherein the first opening has a center area between the first and second ends, and the first opening has a 40% reduction in the center area.

12. The processing system of claim 7, wherein the first opening has a center area between the first and second ends, and the first opening has a 60% reduction in the center area.

13. The processing system of claim 7, wherein the flow valve comprises a plurality of flow valves.

14. The processing system of claim 7, wherein the process chamber includes a side pumping port.

15. A process system, comprising:
a process chamber, comprising:
a substrate support portion;
a chamber body coupled to the substrate support portion, wherein the chamber body comprises a first side and a second side opposite the first side, the chamber body and the substrate support portion cooperatively defining a processing volume;
a liner assembly disposed in the first side, wherein the liner assembly includes a flow valve that is rotatable relative to a centerline of the process chamber; and
a distributed pumping structure located in the substrate support portion adjacent to the second side; and
a remote plasma source coupled to the process chamber by a connector, wherein the connector is connected to the liner assembly to form a fluid flow path from the remote plasma source to the processing volume.
